(19) United States
(12) Patent Application Publication
(10) Pub. No.: US 2024/0265174 A1
(43) Pub. Date: Aug. 8, 2024

(54) SYSTEMS, METHODS AND COMPUTER-ACCESSIBLE MEDIUM FOR PROVIDING A LANGUAGE MODEL POPULATION SIMULATOR

(71) Applicant: NEW YORK UNIVERSITY, NEW YORK, NY (US)

(72) Inventor: ERIC KARL OERMANN, Chapel Hill, NC (US)

(21) Appl. No.: 18/434,053

(22) Filed: Feb. 6, 2024

Related U.S. Application Data
(60) Provisional application No. 63/443,602, filed on Feb. 6, 2023.

(51) Int. Cl. G06F 30/27

(52) U.S. Cl. CPC G06F 30/27

(57) ABSTRACT

Exemplary systems, methods, and computer-accessible medium are provided that that can leverage a large language model (LLM) to determine a prediction of a population level response to presented information. Thus, the exemplary systems, methods, and computer-accessible medium are provided that condition at least one large language model (LLM) agent on a plurality of population or group features using in-weight training or in-context tokens, record an initial memory state of the at least one large language model (LLM) agent, retrieve one or more entries of an LLM agent output from an LLM agent memory to include in the next planning step, plan an LLM agent response to an environment for the presented information, send one or more conditioned intra-agent communications to a plurality of additional LLM agents, receive the one or more conditioned intra-agent communications from the plurality of additional LLM agents, record an updated memory state of the LLM agent based on the one or more sent and received conditioned intra-agent communications, and generate the prediction based on the updated memory state.

### CROSS REFERENCE TO RELATED APPLICATION(S)

This application relates to and claims the benefit of priority from U.S. Provisional Patent Application No. 63/443,602, filed on Feb. 6, 2023, the entire disclosure of which is incorporated herein by reference.

### FILED OF THE DISCLOSURE

The present disclosure relates generally to population simulator(s) for a language model based system, and more specifically, to exemplary embodiments of systems, methods and computer-accessible medium which can simulate the response of a population to a public stimulus using a language model (e.g., a large language model).

### BACKGROUND INFORMATION

A possible challenge when designing public health interventions, as well as public information and misinformation campaigns, is assessing the uptake of the intervention (or information/misinformation in the case of the campaigns) by a given population. Current approaches to achieving this may include the use of focus groups, marketing surveys, polling, and A/B testing interventions within small test scenarios.

Accordingly, there is a need to address and/or improve at least these deficiencies which exist in the previous systems and methods by providing systems, methods and computer-accessible medium that can leverage large language models (LLMs) to simulate and predict intervention uptake within a population or population and or group responses, which can overcome at least some of the deficiencies described herein above.

### SUMMARY OF EXEMPLARY EMBODIMENTS

Exemplary systems, methods and computer-accessible medium according to exemplary embodiments of the present disclosure can be provided which provide that populations of conditional-LLMs can simulate populations of humans. Exemplary systems, methods and computer-accessible medium according to exemplary embodiments of the present disclosure provide for usage of LLMs for population level simulations of human responses to, e.g., public health interventions, political activities, focus group responses, and responsiveness to any misinformation and/or information campaign.

To create or otherwise generate the simulation, exemplary systems, methods and computer-accessible medium according to exemplary embodiments of the present disclosure can facilitate the construction of an exemplary LLM Simulation Engine that can generate a population of LLMs based upon, e.g., demographic, political, ethnic, cultural, educational, and other inputs that are important for measuring population-level or group level responses to a stimulus.

Exemplary systems, methods and computer-accessible medium according to exemplary embodiments of the present disclosure can be used to optimize a given information and/or misinformation campaign to ensure maximal impact on a population.

Exemplary systems, methods and computer-accessible medium according to exemplary embodiments of the present disclosure can include an exemplary population of LLMs that can be jointly stimulated by input information, and then jointly read out a given population level response depending upon their individual outputs. This could be, e.g., votes for a politician, favorability to vaccination, perceptions of a product, or change in beliefs based on information and/or misinformation.

This exemplary population of LLMs can be static, and queried once, and/or can be tied together using a communication mechanism consisting of a graph of one or more nodes to allow communication between LLMs within the population.

On a broad level, exemplary systems, methods and computer-accessible medium according to exemplary embodiments of the present disclosure can be used to simulate and optimize an advertising or marketing campaign for commercial entities.

In some exemplary embodiments of the present disclosure, exemplary systems, methods, and computer accessible medium can be provided which can determine a prediction of a population level response to presented information by conditioning at least one large language model (LLM) agent on a plurality of population or group features using in-weight training or in-context tokens, recording an initial memory state of the at least one LLM agent, retrieving one or more entries of an LLM agent output from an LLM agent memory to include in the next planning step, planning an LLM agent response to an environment for the presented information, sending one or more conditioned intra-agent communications to a plurality of additional LLM agents, receiving the one or more conditioned intra-agent communications from the plurality of additional LLM agents, recording an updated memory state of the LLM agent based on the one or more sent and received conditioned intra-agent communications, and generating the prediction based on the updated memory state

In further exemplary embodiments of the present disclosure, exemplary systems, methods, and computer accessible medium can iterate the steps above for one or more additional time points. Also, the prediction can comprise an election outcome, and the plurality of additional LLM agents can be defined by the environment for the information.

These and other objects, features and advantages of the exemplary embodiments of the present disclosure will become apparent upon reading the following detailed description of the exemplary embodiments of the present disclosure, when taken in conjunction with the appended claims.

### BRIEF DESCRIPTION OF THE DRAWINGS

Further objects, features and advantages of the present disclosure will become apparent from the following detailed description taken in conjunction with the accompanying Figures showing illustrative embodiments of the present disclosure, in which:

FIG. 1 is an exemplary population simulator system according to an exemplary embodiment of the present disclosure;

FIG. 2 is a flow diagram of a method according to an exemplary embodiment of the present disclosure which is used by the exemplary architecture shown in FIG. 1; and

FIG. 3 is a block diagram of an exemplary embodiment of a system according to the present disclosure.

Throughout the drawings, the same reference numerals and characters, unless otherwise stated, are used to denote like features, elements, components or portions of the illustrated embodiments. Moreover, while the present disclosure will now be described in detail with reference to the figures, it is done so in connection with the illustrative embodiments and is not limited by the particular embodiments illustrated in the figures and the appended claims.

### DETAILED DESCRIPTION OF EXEMPLARY EMBODIMENTS

The following description of exemplary embodiments provides non-limiting representative examples referencing numerals to particularly describe features and teachings of different exemplary aspects and exemplary embodiments of the present disclosure. The exemplary embodiments described should be recognized as capable of implementation separately, or in combination, with other exemplary embodiments from the description of the exemplary embodiments. A person of ordinary skill in the art reviewing the description of the exemplary embodiments should be able to learn and understand the different described aspects of the present disclosure. The description of the exemplary embodiments should facilitate understanding of the exemplary embodiments of the present disclosure to such an extent that other implementations, not specifically covered but within the knowledge of a person of skill in the art having read the description of embodiments, would be understood to be consistent with an application of the exemplary embodiments of the present disclosure.

Some large language models (LLMs) such as, e.g., BLOOM, GPT-3, etc. can be trained on massive datasets curated from across the entirety of the internet. From these datasets, these LLMs may learn and memorize the utilization of language to express a wide range of concepts, ideologies, and interactions between people. In the process of doing so, the models may absorb the biases, beliefs, and proclivities inherent in their training datasets.

Through prompt engineering and conditional training, exemplary systems, methods and computer-accessible medium according to exemplary embodiments of the present disclosure can be used to condition these massive models towards certain viewpoints, ideologies, and backgrounds, e.g., in some cases modelling the characteristics of subsets of their datasets. For example, a model prompted as, “I am a White, male, living in rural Idaho. I always vote Republican. I am low income. When I am asked about immigration, I respond: [START]” may comment on its support of conservative immigration policies. Conversely, an exemplary model prompted as, “I am a multi-ethnic, Physician at NYU. I live in Chelsea. When I am asked about getting the COVID-19 vaccine, I say: [START]” may respond that they support vaccination and public health.

Thus, exemplary systems, methods and computer-accessible medium according to exemplary embodiments of the present disclosure can be used to facilitate modelling individuals that can be a powerful capability of LLMs, and can train and/or facilitate LLMs to generate an incredible amount of highly coherent text. The exemplary systems, methods and computer-accessible medium according to the exemplary embodiments of the present disclosure can scale these capabilities from the simulation of individuals to the simulation of populations to predict intervention uptake information pertaining to information/misinformation campaigns, focus group responses, electoral polling, and other group responses.

### Exemplary Purpose of Exemplary Embodiments

An exemplary purpose of the exemplary systems, methods and computer-accessible medium according to exemplary embodiments of the present disclosure can be to simulate the response of a population to a public stimulus. This stimulus can be or include a policy intervention, an advertising or marketing campaign, an information and/or misinformation campaign, a public health intervention, or any other stimulus at the population level. By simulating population level responses to a public stimulus, this simulation can also facilitate the optimization of that stimulus for maximal impact when deployed in the real world.

Alternatively or in addition, the exemplary stimulus can be a poll, and the exemplary simulation of polling results to subsequently allow the shaping of other aspects of a public intervention. Lastly, when combined with a communication mechanism, this exemplary simulation can also be used to track the spread of information and/or misinformation within a population, and its adaptation and alterations during propagation (e.g., the “telephone effect”).

### Exemplary Applications of Exemplary Embodiments

There can be numerous applications for the exemplary systems, methods and computer-accessible medium according to the exemplary embodiments of the present disclosure. Exemplary systems, methods and computer-accessible medium according to exemplary embodiments of the present disclosure can assess the response of populations to public health interventions, particularly vaccination campaigns, and subsequently to optimize a set of public health messages for encouraging vaccine uptake. Other exemplary applications can include, e.g.:
Simulating the outcomes of marketing and/or advertising campaigns.
Optimizing marketing and/or advertising campaign messaging.
Simulated Political Polling and voting
Optimizing Political Messaging
Optimizing and/or tracking misinformation campaigns
Simulating public health interventions

### Exemplary Systems and Methods

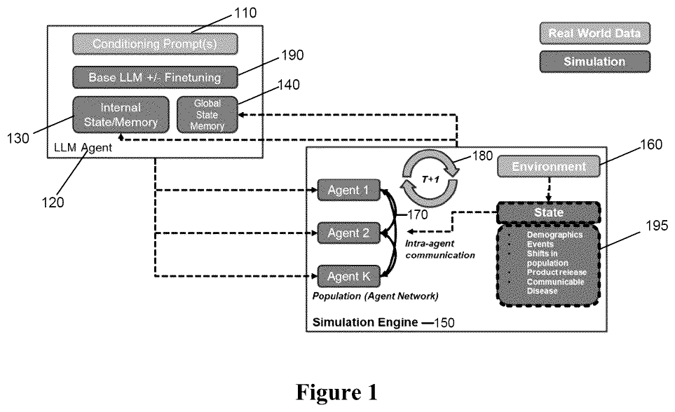

FIG. 1 illustrates an exemplary system according to an embodiment of the present disclosure. Generative large language models (LLMs) serve as valid simulations of human responses to a wide range of text based prompts. When conditioned appropriately through conditioning prompts 110 within the current prompt or a prior one, through time steps 180, these models, comprising a based LLM with or without finetuning 190, can provide a reasonable approximation of a particular individual's (conditional) response to a prompt. These agents 120 can additionally contain discrete memory spaces for storing information about the global simulation 140, and for performing internal reflections/summarizations/chain-of-thought reasoning 130. A population of these conditional LLMs (LLM Agents) 120 can, in turn, approximate the conditional distributions of features within a population. Exemplary systems shown in FIG. 1 can utilize a simulation engine 150 whereby a population of conditional LLMs 120 can be used to model the behaviors of a group or population 195. This exemplary simulation can rely on both the conditional LLMs 120, as well as an underlying environment 160, to interact with the LLMs, and the potential for intra-LLM communication 170 to simulate information dissemination throughout the population. This exemplary system can be used as a type of virtual focus group, simulation of population health interventions, automated market feedback, and/or even as a way of virtual polling.

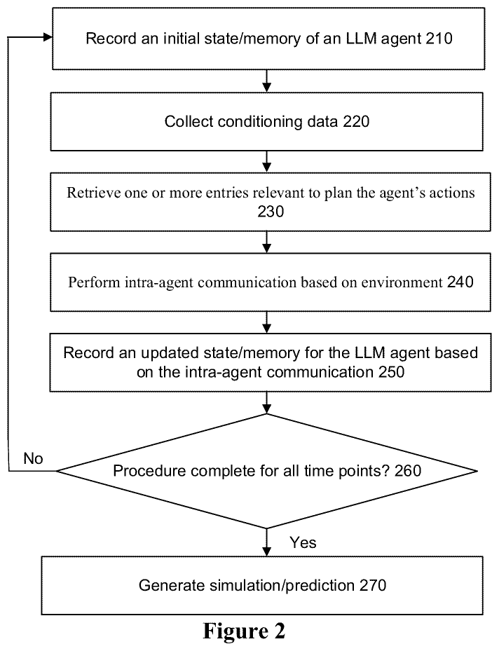

Turning now to FIG. 2 which shows a flow diagram of a method according to an exemplary embodiment of the present disclosure which is used by the exemplary architecture shown in FIG. 1, e.g., at the center of the architecture of the exemplary systems, methods and computer-accessible medium according to exemplary embodiments of the present disclosure can be the conditional LLM agents themselves. According to the exemplary embodiments, each agent can include a database compromising its internal state/memory that can be indexed over time points. As shown in FIG. 2, an initial state can also be recorded by the exemplary systems, methods and computer-accessible medium according of exemplary embodiments at procedure 210 to condition the fundamental characteristics of the agent for the desired simulation or behavior. This initial state can be defined from environmental data, and in many cases can represent the marginal distribution of features in the target population. For example, to simulate a focus group consisting of 30% Hispanics, exemplary systems, methods and computer-accessible medium according to the exemplary embodiments of the present disclosure can ensure that 30% of the agents have “Hispanic” as a component of their initial state implemented as a form of prompting, “You are a Hispanic” or via a hard-coded conditioning token defined by a pre-trained BERT conditioning model.

At procedure 220, the conditioning of individual agents on the conditional distribution of population features or marginal distribution if the conditional is not available according to exemplary embodiments of the present disclosure can be accomplished using real-world data, obtained from a census for example, or from explicitly pre-defining characteristics such as the selection of a jury or a survey group. The exemplary systems, methods and computer-accessible medium according to the exemplary embodiments of the present disclosure can reveal that generalist LLMs already contained powerful signals regarding the relationships, biases, and proclivities of human beings, and that mild conditioning based on these features according to the exemplary embodiments can generate models that accurately model specific subpopulations or individuals for the purposes of social science research.

In the exemplary systems, methods and computer-accessible medium according to exemplary embodiments of the present disclosure, the time stamped database and the initial state contained therein can constitute the agent's memory, with distinct subsections for memory of external events, Global State Memory, and an internal scratchpad “Internal State/Memory”, that the agent can use to store the outputs of reflective prompting at the current or prior timepoints. At procedure 230 of FIG. 2, entries can be retrieved from the database as relevant to plan the agent's actions and responses to the environment or other agents. The entries can be LLM agent outputs from a current or prior time step. The exemplary systems, methods and computer-accessible medium according to exemplary embodiments of the present disclosure can access these entries within a local context window directly using attention, or globally using a RAG-style pipeline of assessing the cosine similarity of the current internal state (consisting of agent's current reflection+communications+compressed global state) with the memory database. The database can additionally be augmented with a summarizing process to condense records when it runs out of memory, allowing for a recurrent process and persistence.

At procedure 240 of FIG. 2, intra-agent communication, according to exemplary systems, methods and computer-accessible medium according to exemplary embodiments of the present disclosure, can be conducted using natural language, and exemplary embodiments can allow each agent to pass a message of natural language text to each other agent or whichever agents it ought to have access to, conditioned on the environment. For example, a group survey or jury can have all-to-all communications, whereas a city might have conditional communication within subgroups (reflecting neighborhoods and subpopulation). In the case of a conditional communication in exemplary embodiments of the present disclosure, the probability of message passing at each time step can be determined by the environment's current state.

An updated internal state/memory can be recorded for each LLM agent at procedure 250 of FIG. 2 based on the conditioning and/or intra-agent communication(s). As indicated herein, this exemplary process can be iterated across various time points at procedure 260 (e.g., to repeat procedure 210-250 until the specific time points or number thereof are reached), and simulation result(s) and/or prediction(s) can be generated at 270 procedure upon reaching the number of points or specific points in time. The process of memory, planning, and reflection can constitute, e.g., the core of generative agents technologies. The exemplary systems, methods and computer-accessible medium according to exemplary embodiments of the present disclosure can utilize these technologies by combining them with inter-agent communication. Using such exemplary configuration, each agent can be conditioned on the marginal distribution of population scale features under a framework where: (a) intra-agent communication can model the marginal distribution of communications within the population, (b) intra-agent actions can model the marginal distribution of communications within the population, and/or (c) the agent population as a whole can model the joint behavior (communications and actions) of the population and provide a viable population level simulation. The exemplary systems, methods and computer-accessible medium according to the exemplary embodiments of the present disclosure can extend to the modelling of elections.

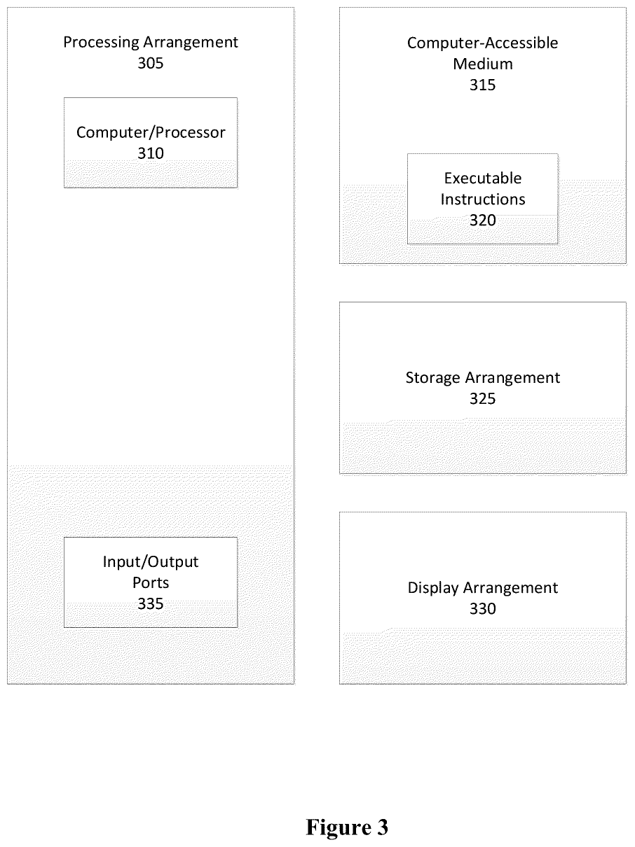

FIG. 3 shows a block diagram of an exemplary embodiment of a system according to the present disclosure. For example, exemplary procedures in accordance with the present disclosure described herein can be performed by a processing arrangement and/or a computing arrangement (e.g., computer hardware arrangement) 305. Such processing/computing arrangement 305 can be, for example entirely or a part of, or include, but not limited to, a computer/processor 310 that can include, for example one or more microprocessors, and use instructions stored on a computer-accessible medium (e.g., RAM, ROM, hard drive, or other storage device).

As shown in FIG. 3, for example a computer-accessible medium 315 (e.g., as described herein above, a storage device such as a hard disk, floppy disk, memory stick, CD-ROM, RAM, ROM, etc., or a collection thereof) can be provided (e.g., in communication with the processing arrangement 305). The computer-accessible medium 315 can contain executable instructions 320 thereon. In addition or alternatively, a storage arrangement 325 can be provided separately from the computer-accessible medium 315, which can provide the instructions to the processing arrangement 305 so as to configure the processing arrangement to execute certain exemplary procedures, processes, and methods, as described herein above, for example. Further, the exemplary processing arrangement 305 can be provided with or include an input/output ports 335, which can include, for example a wired network, a wireless network, the internet, an intranet, a data collection probe, a sensor, etc. As shown in FIG. 3, the exemplary processing arrangement 305 can be in communication with an exemplary display arrangement 330, which, according to certain exemplary embodiments of the present disclosure, can be a touch-screen configured for inputting information to the processing arrangement in addition to outputting information from the processing arrangement, for example. Further, the exemplary display arrangement 330 and/or a storage arrangement 325 can be used to display and/or store data in a user-accessible format and/or user-readable format.

According to exemplary embodiments of the present disclosure, numerous specific details have been set forth. It is to be understood, however, that implementations of the disclosed technology can be practiced without these specific details. In other instances, well-known methods, structures and techniques have not been shown in detail in order not to obscure an understanding of this description. References to “some examples,” “other examples,” “one example,” “an example,” “various examples,” “one embodiment,” “an embodiment,” “some embodiments,” “example embodiment,” “various embodiments,” “one implementation,” “an implementation,” “example “various implementation,” implementations,” “some implementations,” etc., indicate that the implementation(s) of the disclosed technology so described may include a particular feature, structure, or characteristic, but not every implementation necessarily includes the particular feature, structure, or characteristic. Further, repeated use of the phrases “in one example,” “in one exemplary embodiment,” or “in one implementation” does not necessarily refer to the same example, exemplary embodiment, or implementation, although it may.

As used herein, unless otherwise specified the use of the ordinal adjectives “first,” “second,” “third,” etc., to describe a common object, merely indicate that different instances of like objects are being referred to, and are not intended to imply that the objects so described must be in a given sequence, either temporally, spatially, in ranking, or in any other manner.

While certain implementations of the disclosed technology have been described in connection with what is presently considered to be the most practical and various implementations, it is to be understood that the disclosed technology is not to be limited to the disclosed implementations, but on the contrary, is intended to cover various modifications and equivalent arrangements included within the scope of the claims. Although specific terms are employed herein, they are used in a generic and descriptive sense only and not for purposes of limitation.

The foregoing merely illustrates the principles of the disclosure. Various modifications and alterations to the described embodiments will be apparent to those skilled in the art in view of the teachings herein. It will thus be appreciated that those skilled in the art will be able to devise numerous systems, arrangements, and procedures which, although not explicitly shown or described herein, embody the principles of the disclosure and can be thus within the spirit and scope of the disclosure. Various different exemplary embodiments can be used together with one another, as well as interchangeably therewith, as should be understood by those having ordinary skill in the art. In addition, certain terms used in the present disclosure, including the specification and drawings, can be used synonymously in certain instances, including, but not limited to, for example, data and information. It should be understood that, while these words, and/or other words that can be synonymous to one another, can be used synonymously herein, that there can be instances when such words can be intended to not be used synonymously. Further, to the extent that the prior art knowledge has not been explicitly incorporated by reference herein above, it is explicitly incorporated herein in its entirety. All publications referenced are incorporated herein by reference in their entireties.

Throughout the disclosure, the following terms take at least the meanings explicitly associated herein, unless the context clearly dictates otherwise. The term “or” is intended to mean an inclusive “or.” Further, the terms “a,” “an,” and “the” are intended to mean one or more unless specified otherwise or clear from the context to be directed to a singular form.

This written description uses examples to disclose certain implementations of the disclosed technology, including the best mode, and also to enable any person skilled in the art to practice certain implementations of the disclosed technology, including making and using any devices or systems and performing any incorporated methods. The patentable scope of certain implementations of the disclosed technology is defined in the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

### EXEMPLARY REFERENCES

The following references are hereby incorporated by reference, in their entireties:
Gao C, Lan X, Lu Z, Mao J, Piao J, Wang H, Jin D, Li Y (2023) S3: Social-network Simulation System with Large Language Model-Empowered Agents. arXiv [cs.SI], http://arxiv.org/abs/2307.14984
Hu Y, Mai G, Cundy C, Choi K, Lao N, Liu W, Lakhanpal G, Zhou R Z, Joseph K (2023) Geo-knowledge-guided GPT models improve the extraction of location descriptions from disaster-related social media messages. Geographical Information Systems, 37:2289-2318.
Chuang Y-S, Goyal A, Harlalka N, Suresh S, Hawkins R, Yang S, Shah D, Hu J, Rogers T T (2023) Simulating Opinion Dynamics with Networks of LLM-based Agents. arXiv [physics.soc-ph], http://arxiv.org/abs/2311.09618
Li Y, Zhang Y, Sun L (2023) MetaAgents: Simulating Interactions of Human Behaviors for LLM-based Task-oriented Coordination via Collaborative Generative Agents. arXiv [cs.AI], http://arxiv.org/abs/2310.06500
Xiao B, Yin Z, Shan Z (2023) Simulating Public Administration Crisis: A Novel Generative Agent-Based Simulation System to Lower Technology Barriers in Social Science Research. arXiv [cs.CY], http://arxiv.org/abs/2311.06957
Jiang J, Ferrara E (2023) Social-LLM: Modeling User Behavior at Scale using Language Models and Social Network Data. arXiv [cs.SI], http://arxiv.org/abs/2401.00893
Mitsopoulos K, Bose R, Mather B, Bhatia A, Gluck K, Dorr B, Lebiere C, Pirolli P (2023) Psychologically-Valid Generative Agents: A Novel Approach to Agent-Based Modeling in Social Sciences. Proceedings of the AAAI Symposium Series, 2(1):340-348.
Horton J J (2023) Large Language Models as Simulated Economic Agents: What Can We Learn from Homo Silicus? https://doi.org/10.3386/w31122

What is claimed is:

1. A method for determining a prediction of a population level response to presented information, comprising:
(a) conditioning at least one large language model (LLM) agent on a plurality of population or group features using in-weight training or in-context tokens;
(b) recording an initial memory state of the at least one LLM agent;
(c) retrieving one or more entries of an output of the at least one LLM agent from an LLM agent memory to include in the next planning step;
(d) planning a response of the at least one LLM agent to an environment for the presented information;
(e) transmitting one or more conditioned intra-agent communications to a plurality of additional LLM agents;
(f) receiving the one or more conditioned intra-agent communications from the plurality of additional LLM agents;
(g) recording an updated memory state of the LLM agent based on the one or more sent and received conditioned intra-agent communications; and
(h) generating the prediction based on the updated memory state.

2. The method of claim 1, wherein the prediction comprises an election outcome.

3. The method of claim 1, wherein the plurality of additional LLM agents are defined by the environment for the information.

4. The method of claim 1, further comprising, iterating procedures (a)-(h) for one or more additional time points.

5. A system for determining a prediction of a population level response to presented information, comprising:
at least one computer processor configured to:
(a) condition at least one large language model (LLM) agent on a plurality of population or group features using in-weight training or in-context tokens;
(b) record an initial memory state of the at least one LLM agent;
(c) retrieve one or more entries of an output of the at least one LLM agent from an LLM agent memory to include in the next planning step;
(d) plan a response of the at least one LLM agent to an environment for the presented information;
(e) send one or more conditioned intra-agent communications to a plurality of additional LLM agents;
(f) receive the one or more conditioned intra-agent communications from the plurality of additional LLM agents;
(g) record an updated memory state of the LLM agent based on the one or more sent and received conditioned intra-agent communications; and
(h) generate the prediction based on the updated memory state.

6. The system of claim 5, wherein the prediction comprises an election outcome.

7. The system of claim 5, wherein the plurality of additional LLM agents are defined by the environment for the information.

8. The system of claim 5, wherein the at least one computer processor is further configured to iterate procedures (a)-(h) for one or more additional time points.

9. A computer accessible medium which includes software thereon for determining a prediction of a population level response to presented information, wherein, when at least one computer processor executes the software, the computer processor is configured to perform the procedures, comprising
(a) conditioning at least one large language model (LLM) agent on a plurality of population or group features using in-weight training or in-context tokens;
(b) recording an initial memory state of the at least one LLM agent;
(c) retrieving one or more entries of an output of the at least one LLM agent from an LLM agent memory to include in the next planning step;
(d) planning a response of the at least one LLM agent to an environment for the presented information;
(e) sending one or more conditioned intra-agent communications to a plurality of additional LLM agents;
(f) receiving the one or more conditioned intra-agent communications from the plurality of additional LLM agents;
(g) recording an updated memory state of the LLM agent based on the one or more sent and received conditioned intra-agent communications; and
(h) generating the prediction based on the updated memory state.

10. The computer accessible medium of claim 9, wherein the prediction comprises an election outcome.

11. The computer accessible medium of claim 9, wherein the plurality of additional LLM agents are defined by the environment for the information.

12. The computer accessible medium of claim 9, further comprising iterating procedures (a)-(h) for one or more additional time points.
